(19) United States
(12) Patent Application Publication
(10) Pub. No.: US 2005/0211544 A1
(43) Pub. Date: Sep. 29, 2005

(54) Electrical biasing of gas introduction means of plasma apparatus

(75) Inventor: Jeffrey Shane Reiter, Palo Alto, CA (US)

Correspondence Address: SEAGATE TECHNOLOGY LLC;c/o MCDERMOTT WILL & EMERY LLP, 600 13TH STREET, NW, WASHINGTON, DC, 20005-3096, US

(73) Assignee: SEAGATE TECHNOLOGY LLC

(21) Appl. No.: 10/810,638

(22) Filed: Mar. 29, 2004

(51) Int. Cl. C23C 14/34

(52) U.S. Cl. 204/192.2; 204/298.07; 204/192.12

(57) ABSTRACT

A method of treating or processing at least one substrate/workpiece in a plasma comprises steps of: (a) providing an apparatus comprising a chamber defining an interior space; (b) mounting/positioning at least one substrate/workpiece in the interior space; (c) injecting gas(es) into the interior space by means of an electrically isolated gas supply means having at least one outlet orifice; (d) generating a plasma in the interior space; (e) applying a bias potential to the gas supply means to suppress plasma formation at the at least one outlet orifice; and (f) treating/processing the at least one substrate/workpiece in the plasma.

### FIELD OF THE INVENTION

The present invention relates to an apparatus and method for suppressing plasma formation at gas introduction means of plasma apparatus leading to detrimental effects on the plasma process. The invention has particular utility in preventing premature ionization of a reactive gas species injected into a plasma for performing reactive sputter deposition, as in the manufacture of magnetic and magneto-optical (MO) recording media.

### BACKGROUND OF THE INVENTION

Gas plasmas comprised of ionized species are currently widely utilized in industry for performing diverse processing steps in the manufacture of a variety of products, including for example, semiconductor devices, magnetic and magneto-optical (MO) recording media, architectural glass, optical devices such as wavelength selective filters and reflectors, and corrosion resistant and tribological coatings. Frequently, a precursor or reactive gas is introduced, i.e., injected, into the plasma for effecting a particular reaction or other desired effect, e.g., as in performing plasma enhanced chemical vapor deposition (PECVD), plasma surface treatment, plasma reaction, plasma etching, reactive plasma etching, sputter etching, reactive sputter etching, sputter deposition, reactive sputter deposition, ion plating, cathodic arc deposition (CAD), ion beam deposition (IBD), and hybrid plasma treatment processes comprising combinations of at least two of the aforementioned plasma processes.

Sputter deposition techniques involving generation of ionized plasmas are of increasing utility in the manufacture of high performance magnetic and MO recording media, typically in hard disk form. Such media are widely employed in various applications, particularly in the computer industry for data/information storage and retrieval purposes. A magnetic medium in, e.g., disk form, such as utilized in computer-related applications, comprises a non-magnetic substrate, for example, of glass, ceramic, glass-ceramic composite, polymer, metal or metal alloy, typically an aluminum (Al)-based alloy such as aluminum-magnesium (Al—Mg), having at least one major surface on which a layer stack comprising a plurality of thin film layers constituting the medium are sequentially deposited. In the case of longitudinal type magnetic recording media, such layers may include, in sequence from the substrate deposition surface, a plating layer, e.g., of amorphous nickel-phosphorus (Ni—P), a polycrystalline underlayer, typically of chromium (Cr) or a Cr-based alloy such as chromium-vanadium (Cr—V), a longitudinally oriented magnetic layer, e.g., of a cobalt (Co)-based alloy, and a protective overcoat layer, typically of a carbon (C)-based material, such as diamond-like carbon (DLC), having good mechanical (i.e., tribological) and corrosion resistance properties. Perpendicular type magnetic recording media typically comprise, in sequence from the surface of a non-magnetic substrate, an underlayer of a magnetically soft material, at least one non-magnetic interlayer or intermediate layer, a vertically (i.e., perpendicularly) oriented recording layer of a magnetically hard material, and a protective overcoat layer.

A similar situation exists with magneto-optical (MO) media, wherein a layer stack is formed which comprises a reflective layer, typically of a metal or metal alloy, one or more rare-earth thermo-magnetic (RE-TM) alloy layers, one or more dielectric layers, and a protective overcoat layer, for functioning as reflective, transparent, writing, writing assist, and read-out layers, etc.

According to conventional manufacturing technology, a majority (if not all) of the above-described layers constituting multi-layer longitudinal and perpendicular magnetic media, as well as MO recording media, are deposited by means of cathode sputtering processing. For example, the magnetic recording layers are typically fabricated by sputter depositing a Co-based alloy film, wherein the alloying elements are selected to promote desired magnetic and microstructural properties. In the case of longitudinal-type magnetic disk recording media, metallic and metalloidal elements, such as, for example, Cr, Pt, Ta, B, and combinations thereof, have been found to be effective. Similar alloying elements have been found to be useful in the case of perpendicular-type magnetic disk recording media, and in addition, sputter deposition of the Co-based alloys in a reactive atmosphere, i.e., an oxygen (O₂)-containing atmosphere, has been found to be especially effective in controlling (i.e., limiting) exchange coupling between adjacent magnetic grains. In a typical reactive sputtering process utilized for formation of perpendicular-type magnetic recording media, O₂ gas is mixed with an inert sputtering gas, e.g., Ar, and is consumed by the depositing Co-based alloy magnetic film.

FIG. 1 is a simplified, schematic, perspective view of a portion of a conventional sputtering apparatus 1 which may be utilized for performing non-reactive and/or reactive sputtering of magnetic thin films as part of the manufacturing process of disk-shaped magnetic recording media. As illustrated, apparatus 1 comprises a vacuum chamber 2 equipped with an opening 3 for connection to a pumping means for evacuating the interior of the chamber; at least one, preferably a pair of facing sputtering cathode/target assemblies or sources 4, 4′ of conventional type, e.g., a pair of magnetron sputtering guns each connected to a power source (not shown in the figure for illustrative simplicity) for electrical energization; a mounting means (not shown in the figure for illustrative simplicity) for mounting and positioning a substrate/workpiece 5 in the space between the pair of facing sputtering sources, illustratively a disk-shaped substrate for a magnetic recording medium, for receipt of sputtered particle flux on both substrate surfaces; and a gas injector 6 having a gas inlet portion 7 extending outside the chamber 2 for connection to a source of a gas, and a gas outlet portion 8 within the chamber and formed with a plurality of spaced apart gas outlet orifices or nozzles 9 for injecting gas(es), e.g., inert and/or reactive gas(es), into the space between the pair of facing sputtering sources. Illustratively, the gas injector 6 is “wishbone”-shaped, and comprises a pair of arcuately-shaped, tubular gas outlet portions 8.

Currently, introduction of inert or reactive gas at high pressures from about 0.01 mTorr to about 100 Torr into the ionized plasma within the chamber via a gas injector means such as, but not limited to, the illustrated wishbone-shaped means, results in plasma formation at the point(s) of introduction, leading to detrimental effects on the desired process. For example, high density plasma formation adjacent the gas injector means, i.e., at the point(s) of gas introduction or injection, results in premature ionization of the introduced species. However, it is frequently desirable that the process gas(es), whether inert or reactive, be introduced into the chamber and maintained therein as a neutral species, until such time as ionization is desired.

More specifically, premature ionization of inert gas(es) can result in sputter etching (erosion) of the gas delivery/injection means; and premature ionization of reactive gas(es) can result in the aforementioned erosion of the gas delivery/injection means, as well as creation of decomposed species adjacent the gas delivery/injection means rather than at a desired location, e.g., adjacent the target or substrate/workpiece.

In view of the foregoing, there exists a clear need for improved means and methodology for performing plasma processing techniques requiring injection of inert and/or reactive gas(es) into an ionized plasma within a processing chamber. More specifically, there exists a need for improved means and methodology for overcoming the above-described drawbacks and disadvantages associated with sputtering techniques utilized for the manufacture of hard disk magnetic and MO recording media.

The present invention addresses and solves the problems, disadvantages, and drawbacks described supra in connection with conventional means and methodology for plasma processing, e.g., sputter deposition of the various constituent layers of magnetic and MO recording media, while maintaining full compatibility with all aspects of conventional automated manufacturing technology for hard disk magnetic and MO recording media. Further, the means and methodology afforded by the present invention enjoy diverse utility in the manufacture of all manner of devices and products requiring plasma processing.

### DISCLOSURE OF THE INVENTION

An advantage of the present invention is an improved apparatus adapted for treating or processing at least one substrate/workpiece in a plasma.

Another advantage of the present invention is an improved apparatus for performing cathode sputtering processing.

Yet another advantage of the present invention is an improved method for treating or processing at least one substrate/workpiece in a plasma.

Still another advantage of the present invention is an improved apparatus for performing cathode sputtering processing.

Additional advantages and other features of the present invention will be set forth in the description which follows and in part will become apparent to those having ordinary skill in the art upon examination of the following or may be learned from the practice of the present invention. The advantages of the present invention may be realized and obtained as particularly pointed out in the appended claims.

According to an aspect of the present invention, the foregoing and other advantages are obtained in part by an improved apparatus adapted for treating or processing at least one substrate/workpiece in a plasma, comprising:
(a) a chamber defining an interior space;
(b) means for generating a plasma in the interior space of the chamber;
(c) mounting means adapted for positioning at least one substrate/workpiece in the interior space of the chamber for receiving treatment in the plasma; and
(d) a gas supply means for injecting gas(es) into the interior space of the chamber, comprising:
   (i) an inlet portion extending exteriorly of the chamber;
   (ii) an outlet portion extending into the chamber and including at least one outlet orifice for injecting gas(es) into the interior space; and
   (iii) means for applying a bias potential to the gas supply means for suppressing plasma formation at the at least one outlet orifice.

According to preferred embodiments of the invention, the apparatus further comprises:
(e) means for electrically isolating the gas supply means from the chamber and the means for generating the plasma.

In accordance with further preferred embodiments of the present invention, the outlet portion of the gas supply means extends through an electrically insulated opening in a wall of the chamber; the means for applying the bias potential comprises means for applying a DC, AC, or RF bias potential of selected polarity, e.g., a selected polarity DC bias potential of up to about 1,000 V; the interior space of the chamber is adapted to be maintained at a reduced pressure; and the apparatus is adapted to perform a plasma treatment or process selected from the group consisting of: plasma enhanced chemical vapor deposition (PECVD), plasma surface treatment, plasma reaction, plasma etching, reactive plasma etching, sputter etching, reactive sputter etching, sputter deposition, reactive sputter deposition, ion plating, cathodic arc deposition (CAD), ion beam deposition (IBD), and hybrid plasma treatment processes comprising combinations of at least two of the aforementioned plasma processes.

According to particularly preferred embodiments of the present invention, the apparatus is adapted to perform a sputter deposition or reactive sputter deposition process and the means for generating the plasma includes at least one cathode/target assembly, e.g., a spaced-apart pair of cathode/target assemblies and the mounting means is adapted to position at least one substrate/workpiece in the space between the pair of cathode/target assemblies; and the gas supply means is adapted for injecting said gas(es) into the space between the pair of cathode/target assemblies.

Another aspect of the present invention is an improved method of treating or processing at least one substrate/workpiece in a plasma, comprising steps of:
(a) providing an apparatus comprising a chamber defining an interior space;
(b) mounting/positioning at least one substrate/workpiece in the interior space of the chamber;
(c) injecting gas(es) into the interior space of the chamber by means of an electrically isolated gas supply means having at least one outlet orifice;
(d) generating a plasma in the interior space of the chamber;
(e) applying a bias potential to the gas supply means to suppress plasma formation at the at least one outlet orifice; and
(f) treating/processing the at least one substrate/workpiece in the plasma.

According to embodiments of the invention, step (a) comprises providing an apparatus wherein the chamber is adapted to be maintained at a reduced pressure, e.g., step (a) comprises providing an apparatus adapted to perform a plasma treatment or process selected from the group consisting of: plasma enhanced chemical vapor deposition (PECVD), plasma surface treatment, plasma reaction, plasma etching, reactive plasma etching, sputter etching, reactive sputter etching, sputter deposition, reactive sputter deposition, ion plating, cathodic arc deposition (CAD), ion beam deposition (IBD), and hybrid plasma treatment processes comprising combinations of at least two of the aforementioned plasma processes.

Preferred embodiments of the invention include those wherein step (a) comprises providing an apparatus adapted to perform a sputter deposition or reactive sputter deposition process and includes at least one cathode/target assembly, e.g., a spaced-apart pair of cathode/target assemblies; step (b) comprises mounting/positioning the at least one substrate/workpiece in the space between the pair of spaced-apart cathode/target assemblies; and step (c) comprises injecting the gas(es) into the space between the pair of spaced-apart cathode/target assemblies.

Particularly preferred embodiments of the present invention include those wherein step (b) comprises mounting/positioning at least one disk-shaped substrate/workpiece for a magnetic or magneto-optical (MO) recording medium; and step (f) comprises reactive sputtering of a ferromagnetic target material in an oxygen-containing plasma to deposit an oxygen-containing ferromagnetic film on each surface of the at least one disk-shaped substrate/workpiece.

Further preferred embodiments of the invention include those wherein step (c) comprises injecting gas(es) into the interior space of the chamber by means of an electrically isolated gas supply means having an inlet portion extending exteriorly of the chamber and an outlet portion extending into the chamber via an electrically insulated opening in a wall of the chamber; and step (e) comprises applying a selected polarity DC, AC, or RF bias potential, e.g., a selected polarity bias DC potential of up to about 1,000 V.

Additional advantages and aspects of the present invention will become readily apparent to those skilled in the art from the following detailed description, wherein embodiments of the present invention are shown and described, simply by way of illustration of the best mode contemplated for practicing the present invention. As will be described, the present invention is capable of other and different embodiments, and its several details are susceptible of modification in various obvious respects, all without departing from the spirit of the present invention. Accordingly, the drawings and description are to be regarded as illustrative in nature, and not as limitative.

### BRIEF DESCRIPTION OF THE DRAWINGS

The following detailed description of the embodiments of the present invention can best be understood when read in conjunction with the following drawings, in which the various features are not necessarily drawn to scale but rather are drawn as to best illustrate the pertinent features, and in which like reference numerals are employed throughout for designating similar features, wherein:

FIG. 1 is a simplified, schematic perspective view of a conventional sputtering apparatus, as utilized for performing sputter deposition, e.g., reactive sputter deposition, of magnetic films as part of the manufacture of disk-shaped magnetic and/or magneto-optical (MO) recording media; and

FIG. 2 is a simplified, schematic perspective view of an illustrative, but not limitative, embodiment of a sputtering apparatus according to the present invention, adapted for use in the deposition of magnetic films as part of the manufacture of disk-shaped magnetic and/or magneto-optical (MO) recording media.

### DESCRIPTION OF THE INVENTION

The present invention is based upon recognition by the inventor that deleterious premature ionization of inert or reactive gas supplied at high pressures from about 0.01 mTorr to about 100 Torr into an ionized plasma within a chamber of a plasma treatment/processing apparatus via a gas injector means frequently results in plasma formation at the outlet orifices or nozzles of the gas injector means, leading to detrimental effects on the desired process. For example, high density plasma formation adjacent the gas injector means at the of gas injection orifices or nozzles results in premature ionization of the introduced species. However, it is frequently desirable that the process gas(es), whether inert or reactive, be introduced into the plasma chamber and maintained therein as a neutral species, until such time as ionization is desired.

More specifically, premature ionization of inert gas(es) can result in sputter etching (erosion) of the gas delivery/injection means; and premature ionization of reactive gas(es) can result in the aforementioned erosion of the gas delivery/injection means, as well as creation of decomposed species adjacent the gas delivery/injection means rather than at a desired location, e.g., adjacent the target or substrate/workpiece.

The present invention, therefore, affords improved means and methodology for performing plasma processing techniques requiring injection of inert and/or reactive gas(es) into an ionized plasma within a processing chamber. More specifically, the invention provides improved means and methodology for overcoming the above-described drawbacks and disadvantages associated with sputtering techniques utilized for the manufacture of hard disk magnetic and MO recording media, while maintaining full compatibility with all aspects of conventional automated manufacturing technology for hard disk magnetic and MO recording media. Further, the means and methodology afforded by the present invention enjoy diverse utility in the manufacture of all manner of devices and products requiring plasma processing.

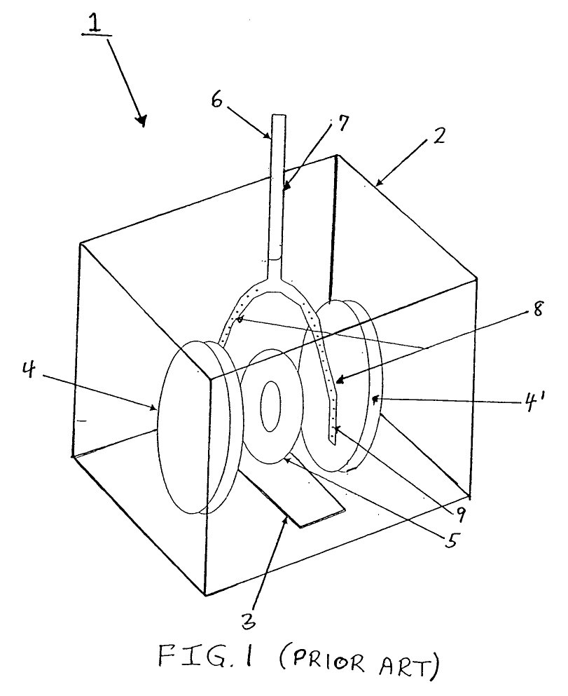

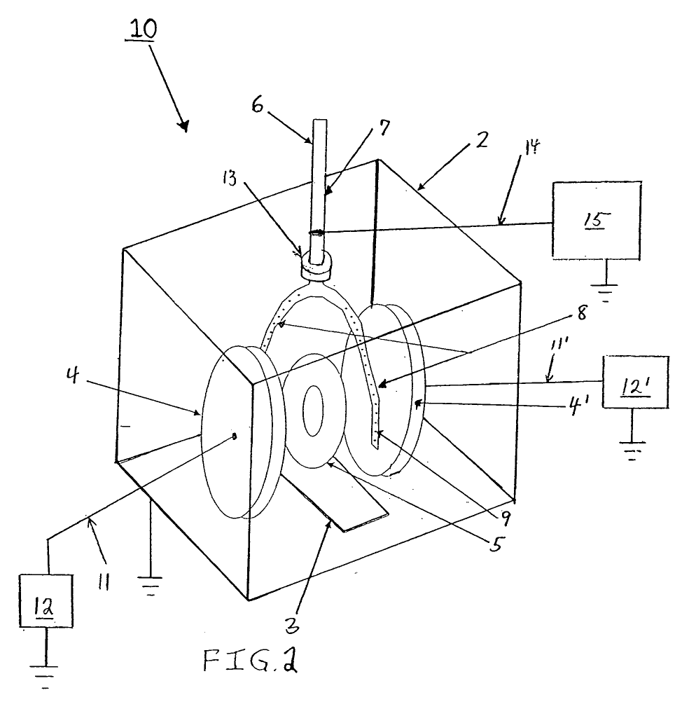

Referring now to FIG. 2, shown therein is a simplified, schematic perspective view of an illustrative, but not limitative, embodiment of a sputtering apparatus 10 according to the present invention, adapted for use in the deposition of magnetic films as part of the manufacture of disk-shaped magnetic and/or magneto-optical (MO) recording media. The illustrated embodiment is similar to the conventional apparatus shown in FIG. 1, but with modifications for providing effective suppression, or at least reduction, of deleterious premature plasma formation and ionization of the injected gas(es).

As shown in FIG. 2, apparatus 10 comprises an electrically grounded vacuum chamber 2 equipped with an opening 3 adapted for connection to a pumping means for evacuating the interior of the chamber; at least one, preferably a pair of facing sputtering cathode/target assemblies or sources 4, 4′ of conventional type, e.g., a pair of magnetron sputtering guns each electrically connected via respective lines 11, 11′ to respective electrically grounded power sources 12, 12′ for electrical energization; a mounting means (not shown in the figure for illustrative simplicity) for mounting and positioning a substrate/workpiece 5 in the space between the pair of facing sputtering sources 4, 4′, illustratively a disk-shaped substrate for a magnetic recording medium, for receipt of sputtered particle flux on both substrate surfaces; and a gas injector 6 fabricated of an electrically conductive material, e.g., a metal, having a gas inlet portion 7 extending outside the chamber 2 and adapted for connection to a source of gas(es), and a gas outlet portion 8 within the chamber and formed with a plurality of spaced apart gas outlet orifices or nozzles 9 for injecting gas(es), e.g., inert and/or reactive gas(es), into the space between the pair of facing sputtering sources. Gas injector 6 is electrically isolated from the chamber 2 and sputtering sources 4, 4′ by means of an electrically insulating sleeve 13 at the opening in the wall of chamber 2 through which the gas inlet portion 6 extends, and is electrically connected, via line 11, to electrically grounded bias power source or supply 15. Illustratively, the gas injector 6 is “wishbone”-shaped, and comprises a pair of arcuately-shaped, tubular gas outlet portions 8. However, the principles of the invention are equally applicable to all manner of gas injectors having different physical configurations and arrangements of outlet orifices and/or nozzles, e.g., linear tube-like and manifold-type arrangements.

According to the invention, bias power source or supply 18 is adapted for supplying gas injector 6 with a DC, AC, or RF bias voltage of selected polarity. Preferably, bias power supply 18 is adapted to supply a selected polarity (i.e., either positive or negative) DC bias voltage of up to about 1,000 V. Selection of a particular or optimum bias voltage and type for use in a specific application can be readily determined by one of ordinary skill in the art, and depends, inter alia, upon the proximity of the gas outlet orifices to the chamber walls, gas pressure, plasma density, and potential differences between the component surfaces.

The inventive concept is not limited to use with sputtering apparatus, but rather is broadly applicable to all manner of treatment/processing apparatus and methodologies utilizing a plasma, e.g., plasma enhanced chemical vapor deposition (PECVD), plasma surface treatment, plasma reaction, plasma etching, reactive plasma etching, sputter etching, reactive sputter etching, sputter deposition, reactive sputter deposition, ion plating, cathodic arc deposition (CAD), ion beam deposition (IBD), and hybrid plasma treatment processes comprising combinations of at least two of the aforementioned plasma processes.

As described above, the invention is of particular utility in the manufacture of disk-shaped magnetic and/or magneto-optical (MO) recording media involving reactive sputtering of a ferromagnetic target material in an oxygen-containing plasma to deposit an oxygen-containing ferromagnetic film on each surface of disk-shaped substrates.

The present invention thus provides a number of advantages over conventional apparatus and methodology for processing/treating substrates/workpieces in plasma-containing atmospheres, such as reactive sputtering of ferromagnetic layers in the fabrication of magnetic recording media. Further, utilization of the inventive apparatus and methodology as part of conventional manufacturing apparatus for hard disk recording media can be readily implemented, in view of the full compatibility of the invention with all other aspects of automated media manufacture. Finally, the inventive apparatus and methodology are broadly applicable to a variety of treating/processing methodologies utilizing plasma-containing atmospheres, e.g., reactive sputtering processing in the manufacture of a number of different products, e.g., coated architectural glass and multi-layer optical coatings.

In the previous description, numerous specific details are set forth, such as specific materials, structures, processes, etc., in order to provide a better understanding of the present invention. However, the present invention can be practiced without resorting to the details specifically set forth. In other instances, well-known processing materials and techniques have not been described in detail, in order not to unnecessarily obscure the present invention.

Only the preferred embodiments of the present invention and but a few examples of its versatility are shown and described in the present invention. It is to be understood that the present invention is capable of use in various other embodiments and is susceptible of changes and/or modifications within the scope of the inventive concept as expressed herein.

1. An apparatus adapted for treating or processing at least one substrate/workpiece in a plasma, comprising:
(a) a chamber defining an interior space;
(b) means for generating a plasma in said interior space of said chamber;
(c) mounting means adapted for positioning at least one substrate/workpiece in said interior space of said chamber for receiving treatment in said plasma; and
(d) a gas supply means for injecting gas(es) into said interior space of said chamber, comprising:
(i) an inlet portion extending exteriorly of said chamber;
(ii) an outlet portion extending into said chamber and including at least one outlet orifice for injecting gas(es) into said interior space; and
(iii) means for applying a bias potential to said gas supply means for suppressing plasma formation at said at least one outlet orifice.

2. The apparatus as in claim 1, further comprising:
(e) means for electrically isolating said gas supply means from said chamber and said means for generating said plasma.

3. The apparatus as in claim 2, wherein:
said outlet portion of said gas supply means extends through an electrically insulated opening in a wall of said chamber.

4. The apparatus as in claim 1, wherein:
said means for applying said bias potential comprises means for applying a DC, AC, or RF bias potential.

5. The apparatus as in claim 4, wherein:
said means for applying said bias potential comprises means for applying a selected polarity DC bias potential of up to about 1,000 V.

6. The apparatus as in claim 1, wherein:
said interior space of said chamber is adapted to be maintained at a reduced pressure.

7. The apparatus as in claim 1, wherein said apparatus is adapted to perform a plasma treatment or process selected from the group consisting of: plasma enhanced chemical vapor deposition (PECVD), plasma surface treatment, plasma reaction, plasma etching, reactive plasma etching, sputter etching, reactive sputter etching, sputter deposition, reactive sputter deposition, ion plating, cathodic arc deposition (CAD), ion beam deposition (IBD), and hybrid plasma treatment processes comprising combinations of at least two of the aforementioned plasma processes.

8. The apparatus as in claim 7, wherein said apparatus is adapted to perform a sputter deposition or reactive sputter deposition process and said means for generating said plasma includes at least one cathode/target assembly.

9. The apparatus as in claim 8, wherein said apparatus comprises a spaced-apart pair of cathode/target assemblies and said mounting means is adapted to position at least one substrate/workpiece in the space between said pair of cathode/target assemblies.

10. The apparatus as in claim 9, wherein said gas supply means is adapted for injecting said gas(es) into said space between said pair of cathode/target assemblies.

11. A method of treating or processing at least one substrate/workpiece in a plasma, comprising steps of:
(a) providing an apparatus comprising a chamber defining an interior space;
(b) mounting/positioning at least one substrate/workpiece in said interior space of said chamber;
(c) injecting gas(es) into said interior space of said chamber by means of an electrically isolated gas supply means having at least one outlet orifice;
(d) generating a plasma in said interior space of said chamber;
(e) applying a bias potential to said gas supply means to suppress plasma formation at said at least one outlet orifice; and
(f) treating/processing said at least one substrate/workpiece in said plasma.

12. The method according to claim 11, wherein:
step (a) comprises providing an apparatus wherein said chamber is adapted to be maintained at a reduced pressure.

13. The method according to claim 12, wherein:
step (a) comprises providing an apparatus adapted to perform a plasma treatment or process selected from the group consisting of: plasma enhanced chemical vapor deposition (PECVD), plasma surface treatment, plasma reaction, plasma etching, reactive plasma etching, sputter etching, reactive sputter etching, sputter deposition, reactive sputter deposition, ion plating, cathodic arc deposition (CAD), ion beam deposition (IBD), and hybrid plasma treatment processes comprising combinations of at least two of the aforementioned plasma processes.

14. The method according to claim 13, wherein:
step (a) comprises providing an apparatus adapted to perform a sputter deposition or reactive sputter deposition process and includes at least one cathode/target assembly.

15. The method according to claim 14, wherein:
step (a) comprises providing an apparatus including a spaced-apart pair of cathode/target assemblies;
step (b) comprises mounting/positioning said at least one substrate/workpiece in the space between said pair of spaced-apart cathode/target assemblies; and
step (c) comprises injecting said gas(es) into said space between said pair of spaced-apart cathode/target assemblies.

16. The method according to claim 15, wherein:
step (b) comprises mounting/positioning at least one disk-shaped substrate/workpiece for a magnetic or magneto-optical (MO) recording medium.

17. The method according to claim 16, wherein:
step (f) comprises reactive sputtering of a ferromagnetic target material in an oxygen-containing plasma to deposit an oxygen-containing ferromagnetic layer on each surface of said at least one substrate/workpiece.

18. The method according to claim 11, wherein:
step (c) comprises injecting gas(es) into said interior space of said chamber by means of an electrically isolated gas supply means having an inlet portion extending exteriorly of said chamber and an outlet portion extending into said chamber via an electrically insulated opening in a wall of said chamber.

19. The method according to claim 11, wherein:
step (e) comprises applying a DC, AC, or RF bias potential.

20. The method according to claim 19, wherein:
step (e) comprises applying a selected polarity DC bias potential of up to about 1,000 V.
